(19) United States
(12) Patent Application Publication
(10) Pub. No.: US 2026/0150343 A1
(43) Pub. Date: May 28, 2026

(54) THIN FILM TRANSISTOR HAVING VERTICAL STRUCTURE, THIN FILM TRANSISTOR UNIT COMPRISING THE SAME METHOD FOR MANUFACTURING THE SAME AND DISPLAY APPARATUS COMPRISING THE SAME

(71) Applicant: LG Display Co., Ltd., Seoul (KR)

(72) Inventors: GaWon YANG, Paju-si (KR); JuHeyuck BAECK, Paju-si (KR); Dohyung LEE, Paju-si (KR)

(73) Assignee: LG Display Co., Ltd., Seoul (KR)

(21) Appl. No.: 19/347,355

(22) Filed: Oct. 1, 2025

(30) Foreign Application Priority Data
Nov. 22, 2024 (KR) 10-2024-0168081

(51) Int. Cl. H10D 30/67; H10D 86/60

(52) U.S. Cl. CPC H10D 30/6736; H10D 30/6757; H10D 86/60

(57) ABSTRACT

The present disclosure relates to a thin film transistor, a thin film transistor unit, a manufacturing method, and a display apparatus including the same. In one embodiment, the thin film transistor comprises a buffer layer having an inclined surface, a bias electrode in the buffer layer, an active layer on the inclined surface and spaced apart from the bias electrode, and a gate electrode at least partially overlapping the active layer. The active layer includes a channel part overlapping the bias electrode, enabling threshold voltage control and stable operation even in compact layouts. Another embodiment provides a method for forming the buffer layer, bias electrode, active layer, and gate electrode in sequence, as well as a display apparatus incorporating the thin film transistor for improved performance in high resolution panels.

### CROSS-REFERENCE TO RELATED APPLICATION

This application claims the benefit of priority benefit of the Republic of Korea Patent Application No. 10-2024-0168081 filed on Nov. 22, 2024, which is hereby incorporated by reference in its entirety.

### BACKGROUND

### Technical Field

The present disclosure relates to a thin film transistor having a vertical structure, a method for manufacturing the thin film transistor, and a display apparatus including the thin film transistor.

### Description of the Related Art

The transistors are widely used as switching devices or driving devices in the field of electronic devices. In particular, thin film transistors are widely used as switching devices in display apparatuses such as liquid crystal display apparatus or organic light emitting device because they may be manufactured on a glass substrate or a plastic substrate.

The description provided in the discussion of the related art section should not be assumed to be prior art merely because it is mentioned in or associated with that section. The discussion of the related art section may include information that describes one or more aspects of the subject technology, and the description in this section does not limit the invention.

### BRIEF SUMMARY

The present disclosure describes a vertical thin film transistor structure that includes a bias electrode embedded within the buffer layer beneath the active layer, with the gate electrode positioned on the opposite side. By applying a negative voltage to the bias electrode, the electric field from the gate can be partially offset, which reduces threshold voltage roll off that typically occurs in short channel thin film transistors. Experimental results show that this arrangement shifts the threshold voltage in the positive direction and suppresses leakage current, allowing stable and reliable operation even in circuits for high resolution displays.

The active layer is formed of one or more oxide semiconductor layers with carefully controlled thicknesses and compositions. A lower oxide semiconductor layer with high carrier mobility, for example using indium rich materials such as IGZO or IZO, is placed near the bias electrode to improve current characteristics, while upper layers are arranged to maintain threshold voltage control and limit leakage. By keeping the high mobility layers within 20 to 50 percent of the total active layer thickness and using a thin bias insulating layer in the range of 5 to 10 nanometers, both electrical performance and manufacturability can be achieved.

The structure also supports the use of multiple thin film transistors connected in parallel or series with shared bias or gate lines, which enables compact layouts for gate drivers and pixel circuits in OLED and LCD panels. The described manufacturing method integrates inclined buffer layers, embedded bias electrodes, and multilayer active semiconductor films on glass or flexible substrates to provide reliable, high resolution, and area efficient display apparatuses.

For example, one embodiment of the present disclosure is to provide a thin film transistor having a vertical structure, which enables securing a channel length even in a small area.

One embodiment of the present disclosure is to provide a thin film transistor with a vertical structure, including a bias electrode disposed within a buffer layer, an active layer disposed on an inclined surface of the buffer layer, and a gate electrode disposed on the opposite side of the bias electrode.

One embodiment of the present disclosure is to provide a thin film transistor in which a rapid change in threshold voltage or roll-off of threshold voltage is reduced or prevented by a bias electrode.

One embodiment of the present disclosure is to provide a thin film transistor in which a high mobility oxide semiconductor layer is disposed on a side far from a gate electrode in an active layer, thereby reducing or preventing a negative shift of threshold voltage.

One embodiment of the present disclosure is to provide a manufacturing method for a thin film transistor having a bias electrode.

Another embodiment of the present disclosure is to provide a display apparatus having excellent reliability, including the thin film transistor as described above.

In order to achieve the above-described technical subject, one embodiment of the present disclosure provides a thin film transistor including a buffer layer having an inclined surface, a bias electrode in the buffer layer, an active layer spaced apart from the bias electrode and disposed on the inclined surface of the buffer layer, and a gate electrode spaced apart from the active layer and at least partially overlapping the active layer, wherein the gate electrode overlaps the active layer on the inclined surface of the buffer layer, and wherein the active layer includes a channel part, and the channel part overlaps the bias electrode. The buffer layer may include a first buffer layer and a second buffer layer on the first buffer layer, and the bias electrode may be between the first buffer layer and the second buffer layer.

A negative (−) voltage may be applied to the bias electrode.

The bias electrode may be disposed across the entire width of the channel part along the width direction of the channel part, a width of the bias electrode may be greater than a width of the channel part, and wherein the width direction may be a direction perpendicular to a direction in which current flows through the channel part

A thickness of bias electrode may be 30 nm to 50 nm.

The thin film transistor may further include a bias insulating layer on the inclined surface of the buffer layer, and the bias insulating layer may be between the active layer and the bias electrode.

A thickness of the bias insulating layer may be 3 nm or more.

The thin film transistor may further include a first electrode and a second electrode spaced apart from each other and respectively connected to the active layer, and at least one of the first electrode and the second electrode may be on the buffer layer.

The bias electrode may not overlap the first electrode and the second electrode.

The active layer may include a first oxide semiconductor layer and a second oxide semiconductor layer on the first oxide semiconductor layer, the second oxide semiconductor layer may be closer to the gate electrode than the first oxide semiconductor layer, and the first oxide semiconductor layer may have a thickness of 50% or less of a total thickness of the active layer

The first oxide semiconductor layer may have a mobility of 20 or more.

The first oxide semiconductor layer may include at least one of an InO based oxide semiconductor material, an IZO (InZnO) based oxide semiconductor material, an ITZO based oxide semiconductor material, an IGZO based oxide semiconductor material, a FIGZO based oxide semiconductor material, and a FIZO based oxide semiconductor material.

A negative voltage may be applied to the bias electrode. The thickness of the first oxide semiconductor layer may be 5 nm or less.

The active layer may further include a third oxide semiconductor layer between the bias electrode and the first oxide semiconductor layer, and the first oxide semiconductor layer may be between the second oxide semiconductor layer and the third oxide semiconductor layer.

Another embodiment of the present disclosure provides a thin film transistor unit including a buffer layer, a first thin film transistor, and a second thin film transistor, wherein the buffer layer may include a first inclined surface and a second inclined surface. The first thin film transistor includes a first bias electrode at the first inclined surface in the buffer layer, a first active layer spaced apart from the first bias electrode and disposed on the first inclined surface, and a first gate electrode spaced apart from the first active layer and at least partially overlapping the first active layer on the first inclined surface, the first active layer includes a first channel part overlapping the first gate electrode, and the first channel part may overlap the first bias electrode. The second thin film transistor includes a second bias electrode at the second inclined surface in the buffer layer, a second active layer spaced apart from the second bias electrode and disposed on the second inclined surface, and a second gate electrode spaced apart from the second active layer and disposed on the second inclined surface and at least partially overlapping the second active layer on the second inclined surface, the second active layer includes a second channel part overlapping the second gate electrode, and the second channel part may overlap the second bias electrode.

The thin film transistor unit may further include a first electrode on the buffer layer and contacting the first active layer and the second active layer, a second electrode spaced apart from the first electrode and contacting the first active layer, and a third electrode spaced apart from the first electrode and contacting the second active layer.

The second electrode and the third electrode may be connected to each other, the first bias electrode and the second bias electrode may be connected to each other, and a voltage applied to the first gate electrode may be same with a voltage applied to the second gate electrode.

A voltage applied to the second electrode may be different from a voltage applied to the third electrode.

Another embodiment of the present disclosure provides a display apparatus including the thin film transistor and a bias wire for applying a voltage to the bias electrode.

Another embodiment of the present disclosure comprising, forming a first buffer layer on a substrate; forming a bias electrode on the first buffer layer, forming a second buffer layer on the bias electrode, patterning the first buffer layer and the second buffer layer to form an inclined surface, forming an active layer on the inclined surface, and forming a gate electrode spaced apart from the active layer on the inclined surface, wherein in the forming the inclined surface, at least a portion of the bias electrode may be exposed from the inclined surface, and at least a portion of the active layer and at least a portion of the gate electrode may overlap with the bias electrode.

The manufacturing method for the thin film transistor further includes forming a bias insulating layer on the second buffer layer before forming the active layer after forming the inclined surface, wherein the bias insulating layer may be formed on the inclined surface so that the bias insulating layer may separate the active layer and the bias electrode.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a plan view of a thin film transistor according to one embodiment of the present disclosure.

FIG. 2 is a cross-sectional view taken along line I-I′ of FIG. 1 according to one embodiment of the present disclosure.

FIG. 3A is a schematic diagram explaining the threshold voltage roll-off (Vth roll-off) of a thin film transistor according to one embodiment of the present disclosure.

FIG. 3B is a circuit diagram for the thin film transistor of FIG. 1 according to one embodiment of the present disclosure.

FIG. 4 is a cross-sectional view of a thin film transistor according to another embodiment of the present disclosure.

FIG. 5 is an enlarged view of portion “A” of FIG. 4 according to another embodiment of the present disclosure.

FIG. 6 is a cross-sectional view of a thin film transistor according to another embodiment of the present disclosure.

FIG. 7 is an enlarged view of portion “B” of FIG. 6 according to another embodiment of the present disclosure.

FIG. 8 is a plan view of a thin film transistor unit according to another embodiment of the present disclosure.

FIG. 9 is a cross-sectional view taken along line II-II′ of FIG. 8 according to another embodiment of the present disclosure.

FIG. 10 is a circuit diagram for the thin film transistor unit of FIG. 8 according to another embodiment of the present disclosure.

FIG. 11 is a plan view of a thin film transistor unit according to another embodiment of the present disclosure.

FIG. 12 is a cross-sectional view taken along line III-III′ of FIG. 11 according to another embodiment of the present disclosure.

FIG. 13 is a circuit diagram for the thin film transistor unit of FIG. 11 according to another embodiment of the present disclosure.

FIGS. 14A to 14G are cross-sectional views illustrating a manufacturing method for a thin film transistor according to one embodiment of the present disclosure.

FIG. 15 is a schematic diagram of a display apparatus according to another embodiment of the present disclosure.

FIG. 16 is a circuit diagram for one pixel of FIG. 15 according to another embodiment of the present disclosure.

Throughout the drawings and the detailed description, unless otherwise described, the same drawing reference numerals should be understood to refer to the same elements, features, and structures.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted or may be briefly discussed. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

The advantages and features of the present disclosure, and the method for achieving them, will become clear with reference to the embodiments described in detail below together with the accompanying drawings. However, the present disclosure is not limited to the embodiments disclosed below, and may be implemented in various other forms. These embodiments are provided to ensure the completeness of the disclosure of the present disclosure, and to enable those skilled in the art to easily understand the disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same components may be referred to by the same reference numerals throughout the specification. In addition, in explaining the present disclosure, if it is determined that a detailed description of a related known technology may unnecessarily obscure the gist of the present disclosure, the detailed description is omitted.

Any implementation described herein as an “example” is not necessarily to be construed as preferred or advantageous over other implementations.

In this specification, when the words “includes,” “has,” and “consists of,” are used, other parts may be added unless the expression “only” is used. When a component is expressed in the singular, the plural is included unless otherwise explicitly stated.

When interpreting a component, it is interpreted as including the error range even if there is no separate explicit description.

When describing a positional relationship, for example, when the positional relationship between two parts is described as ‘on’, ‘above’, ‘below’, ‘next to’, or the like, one or more other parts may be located between the two parts, unless the expression ‘right’ or ‘directly’ is used.

The spatially relative terms “below,” “beneath,” “lower,” “above,” “upper,” and the like may be used to easily describe the relationship of one element or component to another element or component, as illustrated in the drawings. The spatially relative terms should be understood to include different orientations of the elements during use or operation in addition to the orientations depicted in the drawings. For example, if an element illustrated in the drawings is flipped over, an element described as “below” or “beneath” another element may end up being placed “above” the other element. Thus, the exemplary term “below” can include both the above and below directions. Likewise, the exemplary term “above” or “below” can include both the above and below directions.

When describing a temporal relationship, for example, when describing a temporal relationship such as ‘after’, ‘following’, ‘next to’, or ‘before’, it can also include cases where there is no continuity, as long as the expression ‘right away’ or ‘directly’ is not used.

Although the terms first, second, or the like. are used to describe various components, these components are not limited by these terms. These terms are only used to distinguish one component from another. Accordingly, a first component referred to below may also be a second component within the technical concept of the present disclosure.

Also, when an element or layer is “connected,” “coupled,” or “adhered” to another element or layer denotes that the element or layer can not only be directly connected or adhered to another the other element or layer, but also be indirectly connected or adhered to another the other element or layer with one or more intervening elements or layers “disposed,” or “interposed” between the elements or layers, unless otherwise specified. It should be understood to mean that elements may be so disposed to directly contact each other, or may be so disposed without directly contacting each other.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

At least one term should be understood to include all combinations that may be presented from one or more of the associated items. For example, the meaning of “at least one of the first, second, and third items” may mean not only each of the first, second, or third items, but also all combinations of items that may be presented from two or more of the first, second, and third items.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure. Furthermore, the present disclosure is only defined by scopes of claims.

The individual features of the various embodiments of the present disclosure may be partially or wholly combined or combined with each other, and may be technically linked and driven in various ways, and each embodiment may be implemented independently of each other or may be implemented together in a related relationship.

Hereinafter, a thin film transistor and a display apparatus including the same according to an embodiment of the present disclosure will be described in detail with reference to the attached drawings. When adding reference symbols to components in each drawing, the same components may have the same symbols as much as possible even if they are shown in different drawings.

In the embodiments of the present disclosure, the source electrode and the drain electrode are distinguished for convenience of explanation, but the source electrode and the drain electrode may be interchanged. For example, the source electrode according to one embodiment may become the drain electrode in another embodiment, and the drain electrode according to one embodiment may become the source electrode in another embodiment.

Thin film transistors may be classified into amorphous silicon thin film transistors in which amorphous silicon is used as the active layer, polycrystalline silicon thin film transistors in which polycrystalline silicon is used as the active layer, and oxide semiconductor thin film transistors in which oxide semiconductor is used as the active layer, based on the material constituting the active layer.

Among these, oxide semiconductor thin film transistors with high mobility and large resistance variation depending on the oxygen content have the advantage of being able to easily obtain desired properties. In addition, since the oxide constituting the active layer may be formed at a relatively low temperature during the manufacturing process of oxide semiconductor thin film transistors, the manufacturing cost is low. Since oxide semiconductors are transparent due to the nature of oxides, they are also advantageous in implementing transparent displays.

Recently, electronic products have become more highly integrated, and the demand for high-resolution display apparatuses is increasing. For high integration and high resolution, the size and area of thin film transistors need to be reduced. Therefore, it is beneficial to manufacture a thin film transistor in a small area. Thin film transistor with a vertical structure occupies a small area, so they may be formed in a small area.

Thin film transistor with a vertical structure occupying a small area may have a relatively short channel. A short channel section may reduce the size of the thin film transistor and can increase the driving current (ON current) of the thin film transistor. However, if the length of the channel is short, the threshold voltage variation of the thin film transistor increases, and it may be difficult for the thin film transistor to perform a stable switching function. Therefore, it is beneficial to reduce or minimize the threshold voltage variation in a vertical structure thin film transistor having a short channel, so that the thin film transistor may operate stably. Various embodiments of the present disclosure are directed to addressing these shortcomings, and specific embodiments are described below.

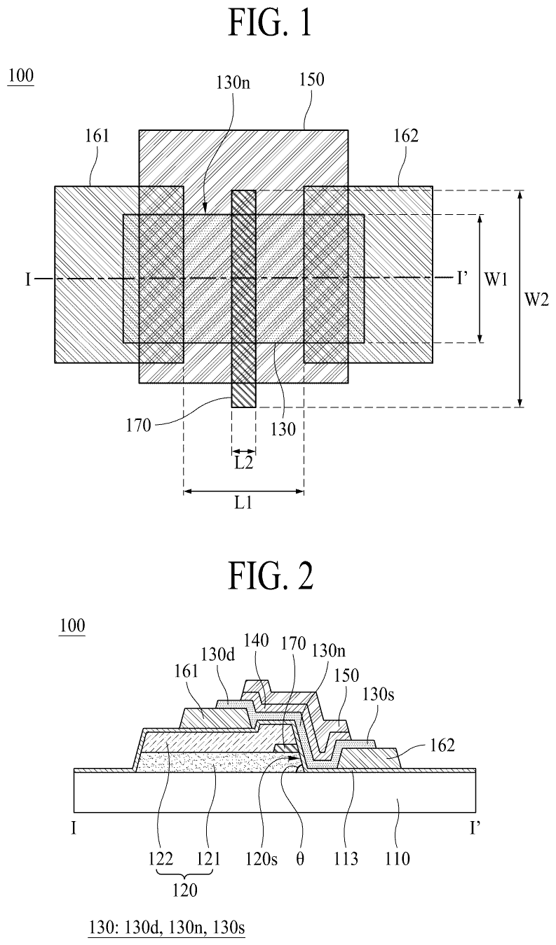

FIG. 1 is a plan view of a thin film transistor 100 according to one embodiment of the present disclosure, and FIG. 2 is a cross-sectional view taken along line I-I′ of FIG. 1.

The thin film transistor 100 according to one embodiment of the present disclosure includes a buffer layer 120 having an inclined surface 120s, a bias electrode 170 in the buffer layer 120, an active layer 130 on the inclined surface 120s of the buffer layer 120 and spaced apart from the bias electrode 170, and a gate electrode 150 spaced apart from the active layer 130 and overlapping at least partly with the active layer 130. The gate electrode 150 overlaps the active layer 130 on the inclined surface 120s of the buffer layer 120. The buffer layer 120 may include a first buffer layer 121 and a second buffer layer 122 on the first buffer layer 121, and the bias electrode 170 may be between the first buffer layer 121 and the second buffer layer 122. The active layer 130 includes a channel part 130n, and the channel part 130n overlaps with the bias electrode 170.

Referring to FIG. 2, a thin film transistor 100 may be disposed on a substrate 110. Any substrate 110 may be used without limitation as long as it supports the thin film transistor 100.

The glass or plastic may be used as the substrate 110. A transparent plastic having flexible properties may be used as the substrate 110. Among the plastics, for example, when polyimide is used as the substrate 110, considering that a high temperature deposition process is performed on the substrate 110, a heat-resistant polyimide that may withstand high temperatures may be used.

The buffer layer 120 is disposed on the substrate 110. The buffer layer 120 may be made of an insulating material. For example, the buffer layer 120 may include at least one of insulating materials such as silicon oxide, silicon nitride, and metal oxide. The buffer layer 120 may block air and moisture to protect the active layer 130. The surface of the upper portion of the substrate 110 may be made uniform by the buffer layer 120.

According to one embodiment of the present disclosure, the buffer layer 120 has an inclined surface 120s. After a buffer material layer is formed on a substrate 110 by a material for forming a buffer layer 120, the buffer material layer is patterned, so that a buffer layer 120 having an inclined surface 120s may be formed.

The inclined surface 120s of the buffer layer 120 may have an inclination angle θ based on the upper surface of the substrate 110. According to one embodiment of the present disclosure, the angle between the upper surface of the substrate 110 and the inclined surface 120s of the buffer layer 120 may be referred to as the inclination angle θ.

According to one embodiment of the present disclosure, the buffer layer 120 may include a first buffer layer 121 and a second buffer layer 122 on the first buffer layer 121. The first buffer layer 121 and the second buffer layer 122 may be made of the same material or may be made of different materials.

After a first buffer material layer for forming a first buffer layer 121 and a second buffer material layer for forming a second buffer layer 122 are formed on a substrate 110, the first buffer material layer and the second buffer material layer may be patterned to form the first buffer layer 121 and the second buffer layer 122.

The first buffer layer 121 and the second buffer layer 122 may each have an inclined surface. According to one embodiment of the present disclosure, in order for simplicity of explanation, the inclined surface of the first buffer layer 121 and the inclined surface of the second buffer layer 122 are not distinguished, and are all referred to as an inclined surface 120s of the buffer layer 120.

In addition, in the embodiments of the present disclosure, in order for simplicity of explanation, the inclination angle of the inclined surface formed in the first buffer layer 121 and the inclination angle of the inclined surface formed in the second buffer layer 122 are not distinguished, and both are referred to as the inclination angle θ of the inclined surface 120s.

According to one embodiment of the present disclosure, the bias electrode 170 is disposed within the buffer layer 120. Referring to FIG. 2, the bias electrode 170 may be disposed between the first buffer layer 121 and the second buffer layer 122. Since the bias electrode 170 is disposed between the first buffer layer 121 and the second buffer layer 122, the bias electrode 170 may be disposed within the buffer layer 120 rather than at the end of the inclined surface 120s formed in the buffer layer 120. By controlling the thickness of the first buffer layer 121 and the second buffer layer 122, the position of the bias electrode 170 may be adjusted.

According to one embodiment of the present disclosure, a portion of the bias electrode 170 may be exposed from the buffer layer 120. Referring to FIG. 2, a side surface of the bias electrode 170 may be exposed to the inclined surface 120s of the buffer layer 120.

Referring to FIG. 2, a bias insulating layer 113 may be disposed on a buffer layer 120. The bias insulating layer 113 is disposed at least on an inclined surface 120s of the buffer layer 120. The bias insulating layer 113 has insulating property. The bias electrode 170 and the active layer 130 may be separated from each other by the bias insulating layer 113.

According to one embodiment of the present disclosure, the bias insulating layer 113 may be disposed on the upper surface and the inclined surface 120s of the buffer layer 120. The bias insulating layer 113 may also be disposed on the entire surface of the substrate 110.

A first electrode 161 and a second electrode 162 may be disposed on a bias insulating layer 113. The first electrode 161 and the second electrode 162 may be spaced apart from each other and may be connected to the active layer 130.

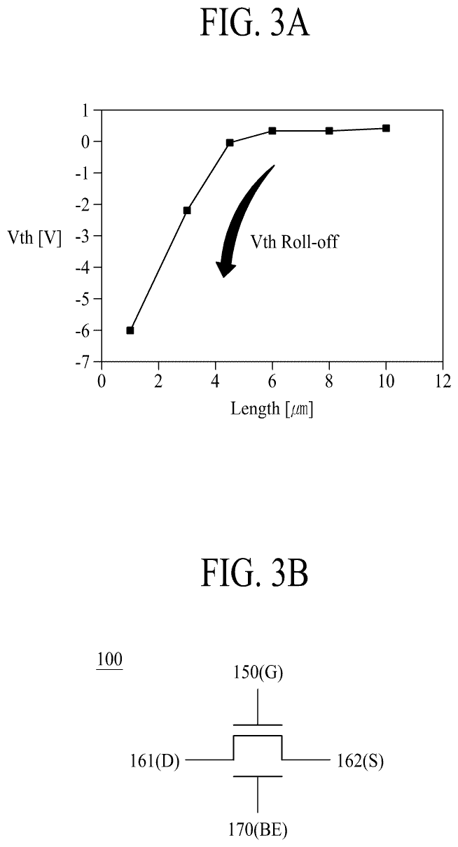

One of the first electrode 161 and the second electrode 162 may serve as a source electrode, and the other may serve as a drain electrode. In FIG. 3B, a circuit diagram in which the first electrode 161 is a drain electrode D and the second electrode 162 is a source electrode S is exemplarily disclosed. However, one embodiment of the present disclosure is not limited thereto, and the first electrode 161 may be a source electrode S and the second electrode 162 may be a drain electrode D.

The first electrode 161 and the second electrode 162 may each include at least one of molybdenum (Mo), aluminum (Al), chromium (Cr), gold (Au), titanium (Ti), nickel (Ni), neodymium (Nd), copper (Cu), and alloys thereof. The first electrode 161 and the second electrode 162 may each be formed of a single layer made of a metal or an alloy of metals, or may be formed of a multilayer having two or more layers.

According to one embodiment of the present disclosure, the first electrode 161 and the second electrode 162 may be disposed on different layers. One of the first electrode 161 and the second electrode 162 may be disposed on the buffer layer 120. The other of the first electrode 161 and the second electrode 162 may be disposed on the substrate 110. The first electrode 161 and the second electrode 162 may be disposed on layers having different heights. The first electrode 161 and the second electrode 162 may have a difference in height.

FIG. 2 discloses an example in which the first electrode 161 is disposed on the buffer layer 120. However, one embodiment of the present disclosure is not limited thereto, and the second electrode 162 may be disposed on the buffer layer 120. Referring to FIG. 2, the second electrode 162 is disposed on the bias insulating layer 113 on the substrate 110. According to one embodiment of the present disclosure, the height may be measured from the upper surface of the substrate 110. A height of a layer may be defined as a distance from the upper surface of the substrate 110 to the upper surface of the layer.

Referring to FIG. 2, an active layer 130 is disposed on the first electrode 161 and the second electrode 162. In addition, the active layer 130 is disposed on a bias insulating layer 113.

Referring to FIG. 1 and FIG. 2, an active layer 130 may be disposed on the first electrode 161, the second electrode 162, and the buffer layer 120. The active layer 130 is disposed on the inclined surface 120s of the buffer layer 120.

In detail, according to one embodiment of the present disclosure, the active layer 130 is disposed on the inclined surface 120s of the buffer layer 120 and spaced apart from the bias electrode 170. The bias insulating layer 113 is disposed between the bias electrode 170 and the active layer 130. The bias insulating layer 113 separates the bias electrode 170 and the active layer 130 from each other.

A part of the active layer 130 may contact the first electrode 161, and another part of the active layer 130 may contact the second electrode 162.

According to one embodiment of the present disclosure, the active layer 130 includes a channel part 130n. The channel part 130n serves as a channel of the thin film transistor 100.

In addition, the active layer 130 includes a first connecting part 130d connected to one side of the channel part 130n and a second connecting part 130s connected to the other side of the channel part 130n. Referring to FIG. 1 and FIG. 2, the first connecting part 130d of the active layer 130 may contact the first electrode 161, and the second connecting part 130s may contact the second electrode 162.

According to one embodiment of the present disclosure, a portion of the active layer 130 that contacts the first electrode 161 may be referred to as a first connecting part 130d, and a portion of the active layer 130 that contacts the second electrode 162 may be referred to as a second connecting part 130s. In addition, a portion between the first connecting part 130d and the second connecting part 130s of the active layer 130 may be referred to as a channel part 130n.

The channel part 130n of the active layer 130 overlaps with the bias electrode 170. In detail, at least a portion of the channel part 130n is disposed on the inclined surface 120s of the buffer layer 120 and overlaps with the bias electrode 170 on the inclined surface 120s.

According to one embodiment of the present disclosure, the active layer 130 may be formed of a semiconductor material. The active layer 130 may include an oxide semiconductor material. The active layer 130 may include, for example, an oxide semiconductor layer.

The active layer 130 may include, for example, at least one of an IGZO (InGaZnO) based oxide semiconductor material, an IGO (InGaO) based oxide semiconductor material, an IGZTO (InGaZnSnO) based oxide semiconductor material, a GZTO (GaZnSnO) based oxide semiconductor material, a GZO (GaZnO) based oxide semiconductor material, a GO (GaO) based oxide semiconductor material, a TO (SnO) based oxide semiconductor material, an ITO (InSnO) based oxide semiconductor material, an ITZO InSnZnO based oxide semiconductor material, an IZO (InZnO) based oxide semiconductor material, a ZO (ZnO) based oxide semiconductor material, an InO (InO) based oxide semiconductor material, a ZnO based oxide semiconductor material, a FIGZO (FeInGaZnO) based oxide semiconductor material, and a FIZO (FeInZnO) based oxide semiconductor material. However, one embodiment of the present disclosure is not limited thereto, and other conventionally known oxide semiconductor materials may be applied to the active layer 130 according to one embodiment of the present disclosure.

According to one embodiment of the present disclosure, the active layer 130 may have a single layer structure or a multilayer structure.

A gate insulating layer 140 is disposed on the active layer 130. The gate insulating layer 140 may include at least one of silicon oxide, silicon nitride, and metal oxide. The gate insulating layer 140 may have a single layer structure or a multilayer structure. The gate insulating layer 140 protects the channel part 130n.

Referring to FIG. 2, the gate insulating layer 140 may be disposed on the channel part 130n disposed on the inclined surface 120s of the buffer layer 120. The channel part 130n of the active layer 130 and the gate electrode 150 may be separated from each other by the gate insulating layer 140.

The gate insulating layer 140 may have a patterned shape. For example, the gate insulating layer 140 may be patterned into a shape corresponding to the gate electrode 150.

However, one embodiment of the present disclosure is not limited thereto, and the gate insulating layer 140 may be formed over the entire upper portion of the substrate 110. For example, the gate insulating layer 140 may cover all of the channel part 130n, the first connecting part 130d, and the second connecting part 130s.

The gate electrode 150 is disposed on the gate insulating layer 140.

The gate electrode 150 may include at least one of an aluminum based metal such as aluminum (Al) or an aluminum Alloy, a silver based metal such as silver (Ag) or a silver alloy, a copper based metal such as copper (Cu) or a copper alloy, a molybdenum based metal such as molybdenum (Mo) or a molybdenum alloy, chromium (Cr), tantalum (Ta), neodymium (Nd), and titanium (Ti). The gate electrode 150 may also have a multilayer structure including at least two conductive layers having different physical properties.

The gate electrode 150 is spaced apart from the active layer 130 and overlaps at least partially with the active layer 130. The gate electrode 150 overlaps the active layer 130 on the inclined surface 120s of the buffer layer 120.

In detail, the gate electrode 150 overlaps at least the channel part 130n of the active layer 130.

According to one embodiment of the present disclosure, the active layer 130 may be disposed between the buffer layer 120 and the gate electrode 150. In addition, the channel part 130n is disposed between the buffer layer 120 and the gate electrode 150. At least a portion of the channel part 130n is disposed between the inclined surface 120s of the buffer layer 120 and the gate electrode 150.

As illustrated in FIG. 2, a thin film transistor 100 having a channel part 130n formed in an inclined surface 120s or formed in a vertical direction is referred to as a vertical thin film transistor (hereinafter, “vertical TFT”). Since the channel part 130n of the vertical TFT is short, it has the advantage of having a large ON current, but has the disadvantage of being difficult to secure the designed threshold voltage Vth due to the short channel length. For example, in a typical vertical TFT, a problem may occur in which the threshold voltage Vth decreases or the threshold voltage Vth moves in a negative direction.

In detail, in the case of vertical TFT, since the length of the channel part is short and the distance between the source electrode and the drain electrode is close, there may be a problem that the threshold voltage Vth is reduced, which may cause a subject in which current flows through the channel part at a voltage lower than the designed voltage. This phenomenon is also called threshold voltage roll-off (Vth roll-off).

FIG. 3A is a schematic diagram explaining the threshold voltage roll-off (Vth roll-off) of a thin film transistor. Referring to FIG. 3A, as the length of the channel part becomes shorter, the threshold voltage of the thin film transistor decreases, and a problem occurs in which the thin film transistor is turned on at a negative (−) voltage.

When threshold voltage roll-off (Vth roll-off) occurs, it becomes difficult to obtain a designed current when a designed voltage is applied, making it difficult to control the thin film transistor.

According to one embodiment of the present disclosure, in order to reduce or prevent threshold voltage roll-off (Vth roll-off) in a thin film transistor 100 having a vertical TFT structure, a bias electrode 170 is disposed on the opposite side of the gate electrode 150.

In detail, the bias electrode 170 is disposed on the opposite side of the gate electrode 150 with respect to the active layer 130.

According to one embodiment of the present disclosure, the bias electrode 170 may play a role of reducing or offsetting the electric field effect generated by the gate electrode 150. To this end, a negative (−) voltage may be applied to the bias electrode 170. Here, the negative (−) voltage refers to a voltage lower than the ground voltage. According to one embodiment of the present disclosure, the reference voltage is the ground voltage.

When a negative (−) voltage is applied to the bias electrode 170, the electric field effect by the gate electrode 150 may be offset or reduced. Therefore, when a negative (−) voltage is applied to the bias electrode 170, the voltage applied to the gate electrode 150 in order to turn on the thin film transistor 100 is relatively higher than the voltage applied to the gate electrode 150 in order to turn on the thin film transistor when the bias electrode 170 is not disposed. As a result, when a negative (−) voltage is applied to the bias electrode 170, the effect of increasing the threshold voltage of the thin film transistor 100 occurs.

According to one embodiment of the present disclosure, by applying a negative (−) voltage to the bias electrode 170, the threshold voltage Vth of the thin film transistor 100 increases, thereby reducing or preventing threshold voltage roll-off (Vth roll-off).

According to one embodiment of the present disclosure, a voltage of −0.5 V to −3 V may be applied to the bias electrode 170.

According to the experiments by the inventors of the present disclosure, it was confirmed that when a voltage of −1.0 V is applied to the bias electrode 170, the threshold voltage Vth of the thin film transistor 100 increases by 10 V or more (positive shift), and when a voltage of −2.0 V is applied to the bias electrode 170, the threshold voltage Vth of the thin film transistor 100 increases by 16 V or more.

When the threshold voltage Vth of the thin film transistor 100 increases, leakage current is reduced or prevented and on-off control of the thin film transistor 100 may become easier.

FIG. 3B is a circuit diagram for the thin film transistor of FIG. 1. Referring to FIG. 3B, the bias electrode 170 (BE) may be disposed to face the gate electrode 150 (G). A constant voltage may be applied to the bias electrode 170 (BE). The voltage applied to the bias electrode 170 is called a bias voltage VBE.

The bias electrode 170 (BE) may be disposed opposite the gate electrode 150 (G) and may suppress or hinder the flow of current or carriers from the first electrode 161, which is the drain electrode D, to the second electrode 162, which is the source electrode S.

According to one embodiment of the present disclosure, the threshold voltage Vth of the thin film transistor 100 may increase when the bias electrode 170 offsets or reduces the electric field effect from the gate electrode 150 even in a part of the channel part 130n. Therefore, the length L2 of the bias electrode 170 is set to be smaller than the length L1 of the channel part 130n (L2<L1).

However, in order to affect the entire current or carrier flowing through the channel part 130n, the bias electrode 170 may be disposed to overlap the entire channel part 130n in the width direction.

In detail, in order to control the current flow in the channel part 130n, the bias electrode 170 is disposed across the entire width of the channel part 130n along the width direction. Here, the width w1, w2 direction is a direction perpendicular to the direction in which current flows through the channel part 130n. Referring to FIG. 1, the width w1, w2 direction is a direction perpendicular to the direction connecting the first electrode 161 and the second electrode 162.

According to one embodiment of the present disclosure, the width w2 of the bias electrode 170 is larger than the width w1 of the channel part 130n (w1<w2). In detail, the bias electrode 170 may have a width capable of cutting off the path of carriers flowing through the channel part 130n.

Since the width w2 of the bias electrode 170 is larger than the width w1 of the channel part 130n, and the bias electrode 170 is disposed across the entire width of the channel part 130n along the width direction, it may affect the entire path of carriers flowing through the channel part 130n overlapping the bias electrode 170.

The thickness of the bias electrode 170 may be set within a range that allows a bias voltage VBE to be stably applied to the bias electrode 170 and reduces or prevents the thickness of the thin film transistor 100 from becoming excessively or unnecessarily thick.

According to one embodiment of the present disclosure, the bias electrode 170 may have a thickness of 30 nm to 50 nm. When the thickness of the bias electrode 170 is 30 nm or more, the bias voltage VBE may be stably applied to the bias electrode 170. Since the bias electrode 170 does not need to be thicker than necessary, the thickness of the bias electrode 170 may be set to 50 nm or less.

When the bias electrode 170 overlaps the first electrode 161 or the second electrode 162, a parasitic cap may be generated. To reduce or prevent the parasitic cap from being generated, according to one embodiment of the present disclosure, the bias electrode 170 is designed so as not to overlap the first electrode 161 and the second electrode 162. In detail, the bias electrode 170 does not overlap the first electrode 161 and the second electrode 162 in the thickness direction, as shown in FIGS. 1 and 2. The bias electrode 170 may not overlap any of the first electrode 161 and the second electrode 162 in a plan view, as shown in FIG. 1.

As the distance between the bias electrode 170 and the channel part 130n becomes closer, the influence of the bias electrode 170 on the channel part 130n may increase. In order to increase the effect of increasing the threshold voltage Vth by the bias electrode 170, the bias insulating layer 113 may have a thin thickness. According to one embodiment of the present disclosure, the bias insulating layer 113 may have a thinner thickness than the gate insulating layer 140.

The bias insulating layer 113 may be formed, for example, by a metal organic chemical vapor deposition (MOCVD) method. A thin bias insulating layer 113 may be formed by a metal organic chemical vapor deposition MOCVD method.

In addition, the bias insulating layer 113 may be formed, for example, by an atomic layer deposition (ALD) method.

The distance between the bias electrode 170 and the channel part 130n may be determined by the bias insulating layer 113. When the bias insulating layer 113 is excessively thin, a short may occur between the bias electrode 170 and the channel part 130n. In order to maintain the insulation between the bias electrode 170 and the channel part 130n, the bias insulating layer 113 may have a thickness of 3 nm or more.

When the distance between the bias electrode 170 and the channel part 130n is greater than 350 nm, the bias electrode 170 may have no effect or little effect on the movement of carriers flowing through the channel part 130n. Accordingly, the bias insulating layer 113 may have a thickness of 350 nm or less.

In detail, considering the influence of the bias insulating layer 113 on the insulation between the bias electrode 170 and the channel part 130n and on the movement of carriers, the bias insulating layer 113 may have a thickness of 5 to 100 nm. In more detail, bias insulating layer 113 may have a thickness of 5 to 10 nm.

The present inventors conducted an experiment to measure the change in threshold voltage Vth of a thin film transistor 100 according to changes in bias voltage VBE applied to a bias electrode 170 and changes of the bias insulating layer 113.

In detail, when the bias voltage VBE applied to the bias electrode 170 is 0 V, −1 V, and −2 V, and the thickness of the bias insulating layer 113 is 3 nm, 5 nm, 10 nm, and 350 nm, the threshold voltages Vth of the thin film transistor 100 are measured. The results of measuring the threshold voltage Vth of the thin film transistor 100 are as shown in Table 1 below.

TABLE 1

| | |
|---|---|
| The thickness of the | Bias voltage VBE (V) |

| | | | |
|---|---|---|---|
| bias insulating layer | 0 V | −1 V | −2 V |

| | | | | |
|---|---|---|---|---|
| 3 | nm | 3.86 | 10.39 | 17.02 |
| 5 | nm | 3.84 | 10.34 | 16.93 |
| 10 | nm | 3.79 | 10.20 | 16.70 |
| 350 | nm | 0.52 | 0.89 | 1.27 |

Referring to Table 1, it may be shown that when the bias insulating layer 113 has a thickness of 3 nm or more, the threshold voltage Vth of the thin film transistor 100 is positive, which means that the threshold voltage Vth of the thin film transistor 100 has been increased or positively shifted. In addition, it is shown that when the thickness of the bias insulating layer 113 is 350 nm, the effect of increasing the threshold voltage Vth of the thin film transistor 100 is not large.

The thin film transistor 100 according to one embodiment of the present disclosure described above has a vertical structure including a channel part 130n disposed on an inclined surface 120s of a buffer layer 120. According to one embodiment of the present disclosure, since the thin film transistor 100 has a vertical structure, the length of the channel part 130n may be secured even in a small area. In addition, since the area occupied by the thin film transistor 100 is small, the thin film transistor 100 may be formed in a small area.

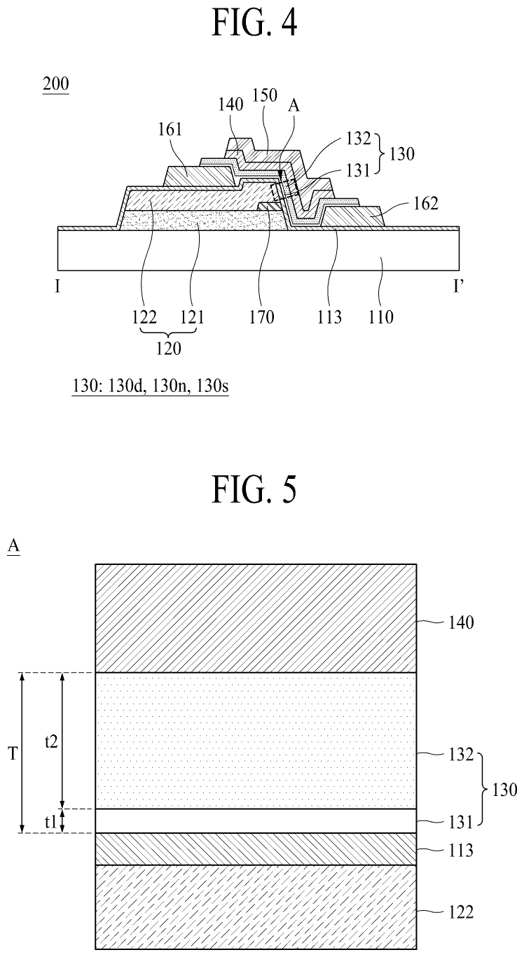

FIG. 4 is a cross-sectional view of a thin film transistor 200 according to another embodiment of the present disclosure. Hereinafter, to avoid duplication, a description of the configuration already described is omitted.

According to another embodiment of the present disclosure, the active layer 130 may include a first oxide semiconductor layer 131 and a second oxide semiconductor layer 132 on the first oxide semiconductor layer 131. Referring to FIG. 4, the second oxide semiconductor layer 132 may be disposed closer to the gate electrode 150 than the first oxide semiconductor layer 131.

According to another embodiment of the present disclosure, in order to improve the current characteristic of the thin film transistor 200, a high mobility oxide semiconductor material may be applied to the first oxide semiconductor layer 131. For example, the first oxide semiconductor layer 131 may include an oxide semiconductor material having a mobility of 20 cm²/V·s or more. In detail, the first oxide semiconductor layer 131 may include an oxide semiconductor material having a mobility of 30 cm²/V·s or more, and may include an oxide semiconductor material having a mobility of 40 cm²/V·s or more.

According to another embodiment of the present disclosure, the first oxide semiconductor layer 131 may have higher mobility than the second oxide semiconductor layer 132. The thin film transistor 200 may have high mobility characteristic due to the first oxide semiconductor layer 131.

According to another embodiment of the present disclosure, an indium based oxide semiconductor material having an indium In content of 30 atomic % (at %) or more based on the total number of metal atoms may be used to form the first oxide semiconductor layer 131. The first oxide semiconductor layer 131 may include, for example, at least one of an InO based oxide semiconductor material, an IZO (InZnO) based oxide semiconductor material, an ITZO (InSnZnO) based oxide semiconductor material, an IGZO (InGaZnO) based oxide semiconductor material, an IGZTO (InGaZnSnO) based oxide semiconductor material, a FIGZO (FeInGaZnO) based oxide semiconductor material, and a FIZO (FeInZnO) based oxide semiconductor material, in which an indium (In) content is 30 atomic % (at %) or more based on the total number of metal atoms.

In detail, the first oxide semiconductor layer 131 may include an indium based oxide semiconductor material having an indium (In) content of 50 atomic % (at %) or more based on the total number of metal atoms.

According to one embodiment of the present disclosure, the first oxide semiconductor layer 131 may have a low oxygen concentration. When the first oxide semiconductor layer 131 includes a high concentration of indium (In) and a low concentration of oxygen, the active layer 130 may have high mobility characteristic and excellent electrical conductivity. The first oxide semiconductor layer 131 may have a higher mobility than the second oxide semiconductor layer 132.

According to one embodiment of the present disclosure, in order to reduce or prevent leakage current and to control the threshold voltage Vth, the first oxide semiconductor layer 131 may be disposed in a portion corresponding to a thickness of 50% or less of the total thickness of the active layer 130. For example, the first oxide semiconductor layer 131 may have a thickness of 50% or less of the total thickness of the active layer 130.

FIG. 5 is an enlarged view of portion “A” of FIG. 4. Referring to FIG. 5, the thickness of the active layer 130 is T, the thickness of the first oxide semiconductor layer 131 is t1, and the thickness of the second oxide semiconductor layer 132 is t2. In FIG. 5, when “T≥t1/2,” it may be said that the first oxide semiconductor layer 131 is disposed in a portion corresponding to a thickness of 50% or less of the total thickness of the active layer 130. In detail, “T/2≥t1” means that the first oxide semiconductor layer 131 has a thickness (t) of 50% or less of the total thickness (T) of the active layer 130.

According to another embodiment of the present disclosure, when a bias electrode 170 is disposed on a buffer layer 120 and a first oxide semiconductor layer 131 is disposed in a portion corresponding to a thickness of 50% or less of the total thickness of the active layer 130, even though a high mobility oxide semiconductor material is applied to the first oxide semiconductor layer 131, it is possible to control the threshold voltage Vth of the thin film transistor 200 having a vertical structure.

In general, since vertical thin film transistors have short channels, when a high mobility oxide semiconductor material is used in the active layer 130, the threshold voltage Vth shifts in the negative (−) direction, which makes it difficult to control the threshold voltage of the thin film transistor and causes leakage current to occur in the thin film transistor.

However, according to one embodiment of the present disclosure, since the bias electrode 170 is disposed in the buffer layer 120, the threshold voltage Vth of the thin film transistor 200 shifts in the positive (+) direction. As a result, leakage current is reduced or prevented from occurring in the thin film transistor 200, and control of the threshold voltage Vth becomes easy.

In addition, as illustrated in FIG. 4, when the first oxide semiconductor layer 131 including a high mobility oxide semiconductor material is disposed in a portion corresponding to a thickness of 50% or less of the total thickness of the active layer 130, it can be alleviated that the carriers are concentrated on the upper surface of the active layer 130, or the concentration of carriers on the upper surface of the active layer 130 may be alleviated. As a result, leakage current in the thin film transistor 200 can be reduced or prevented, and threshold voltage control may be facilitated.

In order to more effectively prevent leakage current, the first oxide semiconductor layer 131 may be disposed in a portion corresponding to a thickness of 20% or less of the total thickness of the active layer (0.2×T≥t1). For example, the first oxide semiconductor layer 131 may have a thickness of 20% or less of the total thickness of the active layer 130.

The first oxide semiconductor layer 131 used to increase carrier concentration and improve mobility may have a thin thickness. According to another embodiment of the present disclosure, even though the first oxide semiconductor layer 131 has a thickness of 5 nm or less, the carrier concentration and mobility of the active layer 130 may be improved. On the other hand, when the first oxide semiconductor layer 131 having high mobility characteristic is thicker than necessary, leakage current may occur in the thin film transistor 200 due to excessive carrier concentration.

Therefore, according to another embodiment of the present disclosure, the first oxide semiconductor layer 131 may have a thickness of 5 nm or less.

On the other hand, when the thickness of the first oxide semiconductor layer 131 is excessively thin, the stability of the film may be reduced, and the effects of increasing carrier concentration and increasing mobility may hardly be exhibited. Therefore, according to another embodiment of the present disclosure, the first oxide semiconductor layer 131 may have a thickness of 2 nm or more.

In detail, according to another embodiment of the present disclosure, the first oxide semiconductor layer 131 may have a thickness of 2 nm to 5 nm, and more specifically, may have a thickness of 2 nm to 3 nm.

The first oxide semiconductor layer 131 may be formed, for example, by a metal organic chemical vapor deposition (MOCVD) method. By the metal organic chemical vapor deposition method, the first oxide semiconductor layer 131, which has a small thickness, cam be formed. In addition, the first oxide semiconductor layer 131 may be formed by an atomic layer deposition (ALD) method.

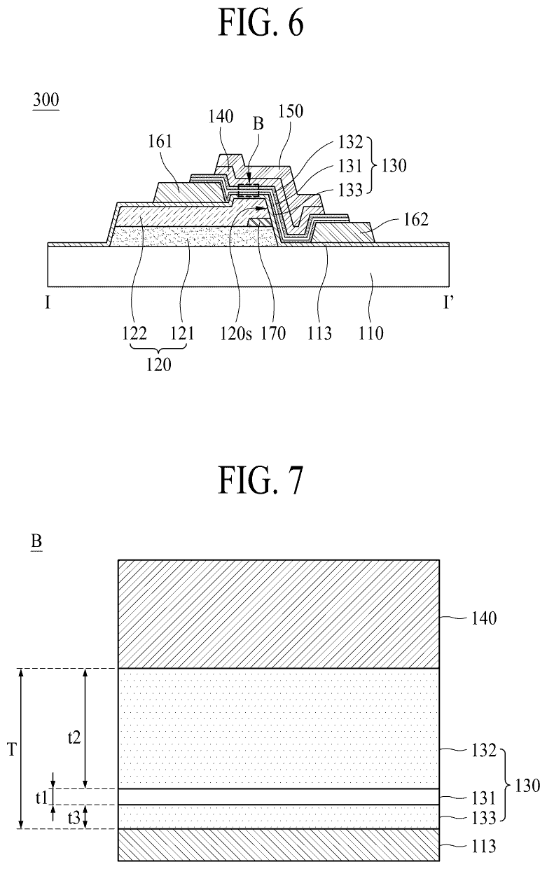

FIG. 6 is a cross-sectional view of a thin film transistor 300 according to another embodiment of the present disclosure.

Compared to the thin film transistor 200 of FIG. 2, the thin film transistor 300 of FIG. 6 may further include a third oxide semiconductor layer 133 in the active layer 130.

According to another embodiment of the present disclosure, the active layer 130 may further include a third oxide semiconductor layer 133 disposed between the bias electrode 170 and the first oxide semiconductor layer 131. The first oxide semiconductor layer 131 may be disposed between the second oxide semiconductor layer 132 and the third oxide semiconductor layer 133.

According to another embodiment of the present disclosure, the third oxide semiconductor layer 133 may have high mobility characteristic. According to another embodiment of the present disclosure, in order to reduce or prevent leakage current and control the threshold voltage Vth, the third oxide semiconductor layer 133 may be disposed in a portion corresponding to a thickness of 50% or less of the total thickness of the active layer 130.

Considering that the thickness of the active layer 130 is about 30 nm to 50 nm, the third oxide semiconductor layer 133 may have a thickness of 10 nm or less. In detail, the third oxide semiconductor layer 133 may have a thickness of 5 nm or less, may have a thickness of 3 nm or less, or may have a thickness of about 2 nm.

FIG. 7 is an enlarged view of part “B” of FIG. 6. When the thickness of the third oxide semiconductor layer 133 is t3, “T/2≥(t1+t3)” may be satisfied. In detail, the first oxide semiconductor layer 131 and the third oxide semiconductor layer 133 may be disposed in a portion corresponding to a thickness of 50% or less of the total thickness of the active layer 130. For example, the first oxide semiconductor layer 131 and the third oxide semiconductor layer 133 may have a thickness of 50% or less of the total thickness of the active layer 130.

In addition, in order to more effectively prevent leakage current, the third oxide semiconductor layer 133 may be disposed in a portion corresponding to a thickness of 20% or less of the total thickness of the active layer. For example, “0.2×T≥(t1+t3)” may be satisfied. In detail, the first oxide semiconductor layer 131 and the third oxide semiconductor layer 133 may be disposed in a portion corresponding to a thickness of 20% or less of the total thickness of the active layer 130. For example, the first oxide semiconductor layer 131 and the third oxide semiconductor layer 133 may have a thickness of 20% or less of the total thickness of the active layer 130.

According to another embodiment of the present disclosure, two or more vertical thin film transistors may be manufactured to be connected to each other.

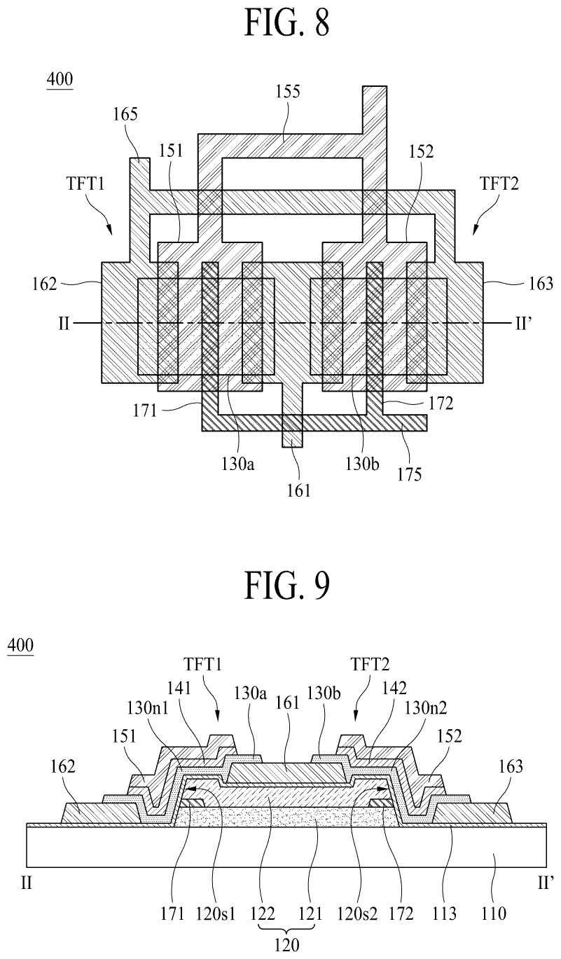

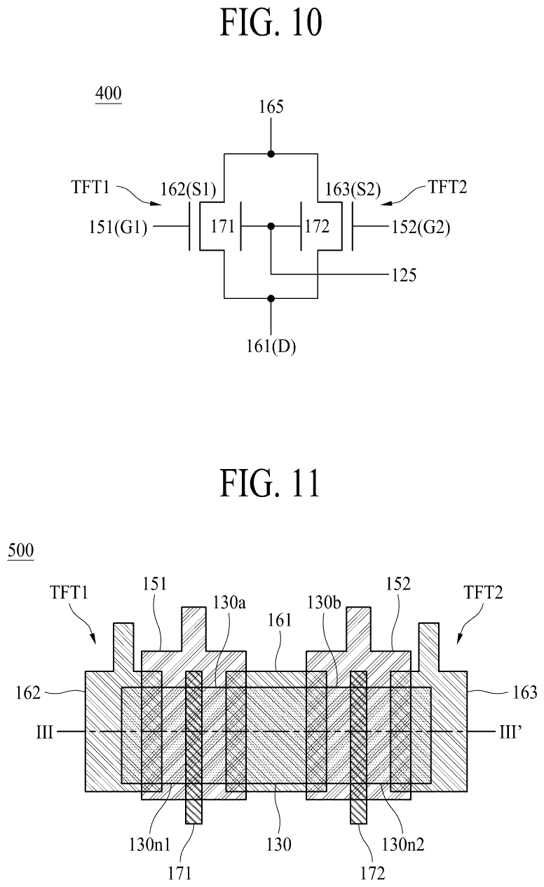

FIG. 8 is a plan view of a thin film transistor unit 400 according to another embodiment of the present disclosure, FIG. 9 is a cross-sectional view taken along line II-II′ of FIG. 8, and FIG. 10 is a circuit diagram for the thin film transistor unit 400 of FIG. 8.

A thin film transistor unit 400 according to another embodiment of the present disclosure includes a buffer layer 120, a first thin film transistor TFT1, and a second thin film transistor TFT2.

Referring to FIG. 8, the buffer layer 120 has a first inclined surface 120s1 and a second inclined surface 120s2. In addition, the buffer layer 120 may include a first buffer layer 121 and a second buffer layer 122 on the first buffer layer 121. The first buffer layer 121 and the second buffer layer 122 may be made of the same material or may be made of different materials.

The first buffer layer 121 and the second buffer layer 122 may each have an inclined surface. According to another embodiment of the present disclosure, without distinguishing between the inclined surface of the first buffer layer 121 and the inclined surface of the second buffer layer 122, the inclined surface of one side of the buffer layer 120 is referred to as the first inclined surface 120s1, and the inclined surface of the other side of the buffer layer 120 is referred to as the second inclined surface 120s2.

The first thin film transistor TFT1 may have a structure identical to or similar to the thin film transistor 100 of FIG. 2, the thin film transistor 200 of FIG. 4, or the thin film transistor 300 of FIG. 6, except for the direction of the inclined surface 120s. The second thin film transistor TFT2 may have a structure identical to or similar to the thin film transistor 100 of FIG. 2, the thin film transistor 200 of FIG. 4, or the thin film transistor 300 of FIG. 6, except for the third electrode 163. Hereinafter, descriptions of the configurations already described are omitted to avoid duplication.

Referring to FIG. 8 and FIG. 9, the first thin film transistor TFT1 includes a first bias electrode 171 disposed on the first inclined surface 120s1 within the buffer layer 120.

The first bias electrode 171 is disposed within the buffer layer 120. Referring to FIG. 9, the first bias electrode 171 may be disposed between the first buffer layer 121 and the second buffer layer 122. A side surface of the first bias electrode 171 may be exposed to the first inclined surface 120s1 of the buffer layer 120.

A bias insulating layer 113 may be disposed on the first inclined surface 120s1.

The first active layer 130a is spaced apart from the first bias electrode 171 and is disposed on the first inclined surface 120s1.

In detail, the first active layer 130a may be disposed on a bias insulating layer 113. The bias insulating layer 113 may be disposed between the first bias electrode 171 and the first active layer 130a.

The first active layer 130a may include an oxide semiconductor material.

In FIG. 9, the first active layer 130a is described as a single layer structure. However, one embodiment of the present disclosure is not limited thereto, and the first active layer 130a may include a first oxide semiconductor layer 131 and a second oxide semiconductor layer 132 on the first oxide semiconductor layer 131. In addition, the first active layer 130a may further include a third oxide semiconductor layer 133 disposed between the first bias electrode 171 and the first oxide semiconductor layer 131.

A first gate insulating layer 141 is disposed on the first active layer 130a.

A first gate electrode 151 is disposed on a first gate insulating layer 141. The first gate electrode 151 is disposed on a first inclined surface 120s1 spaced apart from the first active layer 130a. The first gate electrode 151 at least partially overlaps the first active layer 130a on the first inclined surface 120s1.

The first active layer 130a includes a first channel part 130n1 overlapping the first gate electrode 151. The first channel part 130n1 overlaps the first bias electrode 171.

Referring to FIG. 8 and FIG. 9, the second thin film transistor TFT2 includes a second bias electrode 172 disposed on the second inclined surface 120s2 within the buffer layer 120.

The second bias electrode 172 is disposed in the buffer layer 120. Referring to FIG. 9, the second bias electrode 172 may be disposed between the first buffer layer 121 and the second buffer layer 122. A side surface of the second bias electrode 172 may be exposed to the second inclined surface 120s2 of the buffer layer 120.

A bias insulating layer 113 may be disposed on the second inclined surface 120s2. The bias insulating layer 113 may extend from the first inclined surface 120s1 to the second inclined surface 120s2.

The second active layer 130b is spaced apart from the second bias electrode 172 and is disposed on the second inclined surface 120s2.

In detail, the second active layer 130b may be disposed on the bias insulating layer 113. The bias insulating layer 113 may be disposed between the second bias electrode 172 and the second active layer 130b.

The second active layer 130b may include an oxide semiconductor material.

In FIG. 9, the second active layer 130b is described as a single layer structure. However, one embodiment of the present disclosure is not limited thereto, and the second active layer 130b may include a first oxide semiconductor layer 131 and a second oxide semiconductor layer 132 on the first oxide semiconductor layer 131. In addition, the second active layer 130b may further include a third oxide semiconductor layer 133 disposed between the second bias electrode 172 and the first oxide semiconductor layer 131.

The structure in which the first active layer 130a and the second active layer 130b are formed independently is described in FIG. 8 and FIG. 9, as an example. However, one embodiment of the present disclosure is not limited thereto, and the first active layer 130a and the second active layer 130b may be formed integrally. For example, the first active layer 130a and the second active layer 130b may be connected to each other.

A second gate insulating layer 142 is disposed on the second active layer 130b.

A second gate electrode 152 is disposed on the second gate insulating layer 142. The second gate electrode 152 is disposed on the second inclined surface 120s2 and spaced apart from the second active layer 130b. The second gate electrode 152 at least partially overlaps the second active layer 130b on the second inclined surface 120s2.

The second active layer 130b includes a second channel part 130n2 overlapping the second gate electrode 152. The second channel part 130n2 overlaps the second bias electrode 172.

Referring to FIG. 8 and FIG. 9, a thin film transistor unit 400 according to another embodiment of the present disclosure may include a first electrode 161, a second electrode 162, and a third electrode 163. The first electrode 161, the second electrode 162, and the third electrode 163 may be disposed on a bias insulating layer 113.

Referring to FIG. 8 and FIG. 9, the first electrode 161 is disposed on the buffer 120 layer and contacts the first active layer 130a and the second active layer 130b.

The second electrode 162 is spaced apart from the first electrode 161 and contacts the first active layer 130a.

The third electrode 163 is spaced apart from the first electrode 161 and contacts the second active layer 130b.

According to another embodiment of the present disclosure, the first thin film transistor TFT1 of the thin film transistor unit 400 may include the first electrode 161 and the second electrode 162.

One of the first electrode 161 and the second electrode 162 may serve as a source electrode of the first thin film transistor TFT1, and the other may serve as a drain electrode. In FIG. 10, a circuit diagram is exemplarily disclosed in which the first electrode 161 is a drain electrode D and the second electrode 162 is a source electrode S1 of the first thin film transistor TFT1.

According to another embodiment of the present disclosure, the second thin film transistor TFT2 of the thin film transistor unit 400 may include the first electrode 161 and the third electrode 163.

One of the first electrode 161 and the third electrode 163 may serve as a source electrode of the second thin film transistor TFT2, and the other may serve as a drain electrode. In FIG. 10, a circuit diagram is exemplarily disclosed in which the first electrode 161 is a drain electrode D and the third electrode 163 is a source electrode S2 of the second thin film transistor TFT2.

Referring to FIG. 8 and FIG. 10, the first thin film transistor TFT1 and the second thin film transistor TFT2 are connected in parallel. Referring to FIG. 8 and FIG. 10, the second electrode 162 and the third electrode 163 are connected to each other, the first bias electrode 171 and the second bias electrode 172 are connected to each other, and the same voltage may be applied to the first gate electrode 151 and the second gate electrode 152.

In detail, the second electrode 162 and the third electrode 163 are connected to each other by a source wire 165, so that the same voltage may be applied to the second electrode 162 and the third electrode 163. A voltage applied to the second electrode 162 may be same with a voltage applied to the third electrode 163.

The first bias electrode 171 and the second bias electrode 172 are connected to each other by a bias wire 175, so that the same voltage may be applied to the first bias electrode 171 and the second bias electrode 172. A voltage applied to the first bias electrode 171 may be same with a voltage applied to the second bias electrode 172.

The first gate electrode 151 and the second gate electrode 152 are connected to each other by a gate wire 155, so that the same voltage may be applied to the first gate electrode 151 (G1) and the second gate electrode 152 (G2). A voltage applied to the first gate electrode 151 may be same with a voltage applied to the second gate electrode 152.

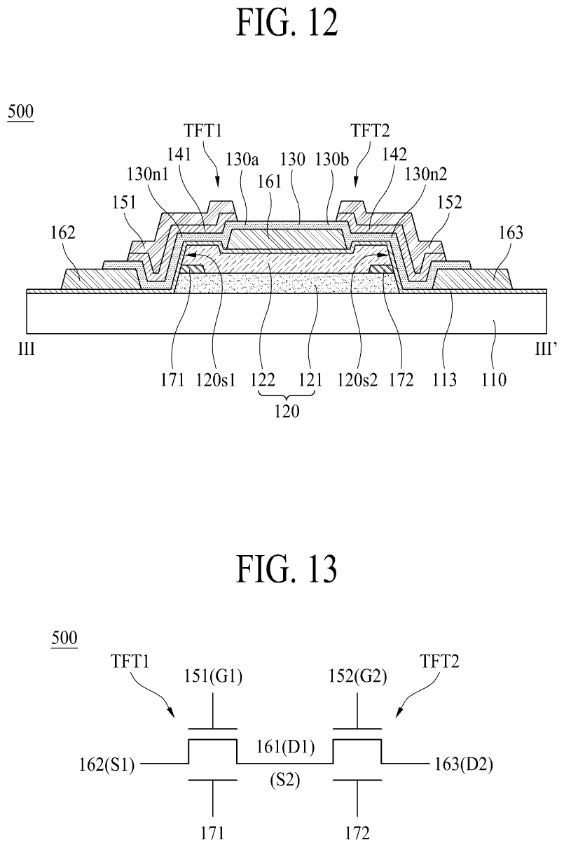

FIG. 11 is a plan view of a thin film transistor unit 500 according to another embodiment of the present disclosure, FIG. 12 is a cross-sectional view taken along line III-III′ of FIG. 11, and FIG. 13 is a circuit diagram for the thin film transistor unit 500 of FIG. 11.

Referring to FIG. 11 and FIG. 13, a first thin film transistor TFT1 and a second thin film transistor TFT2 are connected in series. In addition, referring to FIG. 11 and FIG. 13, a first active layer 130a and a second active layer 130b may be formed integrally.

Referring to FIG. 11 and FIG. 13, voltage may be applied independently to the second electrode 162 and the third electrode 163, voltage may be applied independently to the first bias electrode 171 and the second bias electrode 172, and voltage may be applied independently to the first gate electrode 151 and the second gate electrode 152.

However, even in the structures illustrated in FIG. 11 and FIG. 13, the same voltage may be applied to the first bias electrode 171 and the second bias electrode 172.

Referring to FIG. 11 and FIG. 13, current may flow from the first thin film transistor TFT1 to the second thin film transistor TFT2. Additionally, current may flow from the second thin film transistor TFT2 to the first thin film transistor TFT1.

When the first thin film transistor TFT1 and the second thin film transistor TFT2 are connected in series, different voltages may be applied to the second electrode 162 and the third electrode 163. A voltage applied to the second electrode 162 may be different from a voltage applied to the third electrode 163. A voltage applied to the first gate electrode 151 may be different from a voltage applied to the second gate electrode 152.

In FIG. 13, a circuit diagram is exemplarily described in which the second electrode 162 is the source electrode S1 of the first thin film transistor TFT1 and the first electrode 161 is the drain electrode D1 of the first thin film transistor TFT1.

In addition, the first electrode 161 may be the source electrode S2 of the second thin film transistor TFT2. In FIG. 13, a circuit diagram is exemplarily described in which the first electrode 161 is the source electrode S2 of the second thin film transistor TFT2 and the third electrode 163 is the drain electrode D2 of the second thin film transistor TFT2.

Hereinafter, a manufacturing method for a thin film transistor according to one embodiment of the present disclosure will be described.

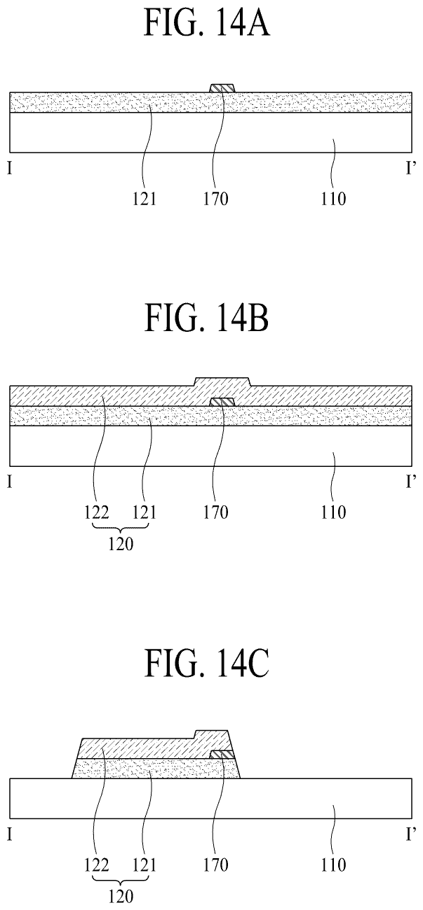

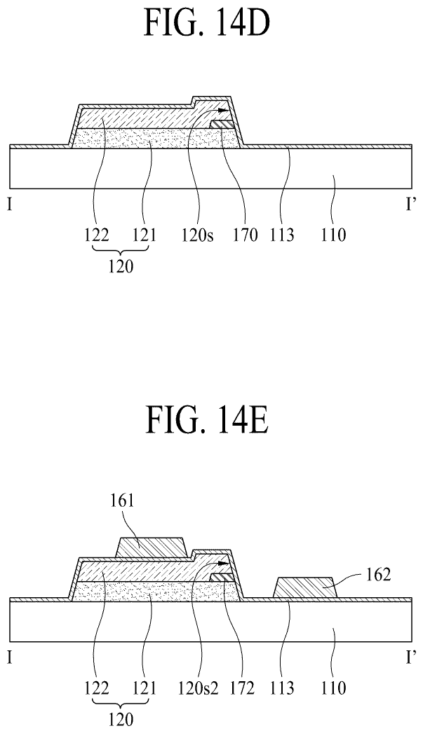

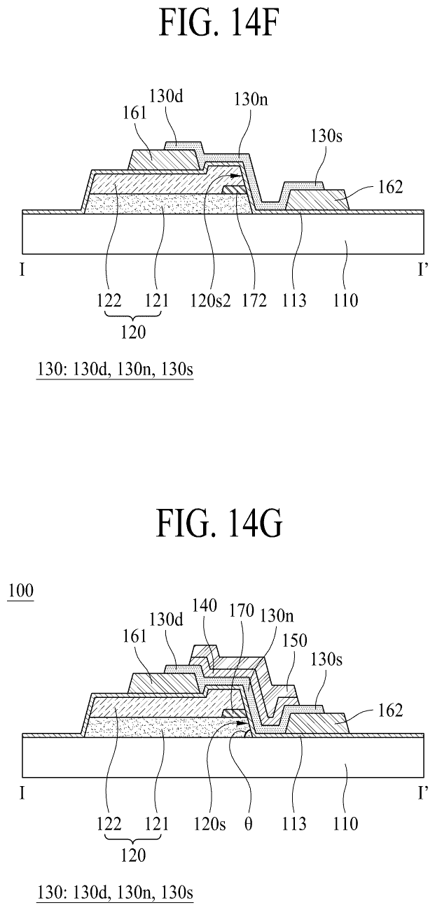

FIG. 14A to 14G are cross-sectional views illustrating a manufacturing method for a thin film transistor 100 according to one embodiment of the present disclosure.

A manufacturing method for a thin film transistor 100 according to one embodiment of the present disclosure includes a step of forming a buffer layer 120 on a substrate 110.

In detail, referring to FIG. 14A, a first buffer layer 121 is formed on a substrate 110. Additionally, a bias electrode 170 is formed on the first buffer layer 121.

Next, referring to FIG. 14B, a second buffer layer 122 is formed on the bias electrode 170. The buffer layer 120 is formed by the first buffer layer 121 and the second buffer layer 122. The bias electrode 170 is placed within the buffer layer 120.

Referring to FIG. 14C, the first buffer layer 121 and the second buffer layer 122 are patterned. As a result, an inclined surface 120s is formed in the buffer layer 120. In forming the inclined surface 120s, at least a portion of the bias electrode 170 may be exposed from the inclined surface 120s.

Referring to FIG. 14D, a bias insulating layer 113 is formed on the second buffer layer 122. A bias insulating layer 113 is also formed on the inclined surface 120s of the buffer layer 120. The bias insulating layer 113 may be disposed on the substrate 110.

Referring to FIG. 14E, a first electrode 161 and a second electrode 162 are formed on a bias insulating layer 113.

The first electrode 161 may be formed on the second buffer layer 122, and the second electrode 162 may be formed on the substrate 110.

Referring to FIG. 14F, an active layer 130 is formed on an inclined surface 120s of a buffer layer 120. The active layer 130 may be formed on a bias insulating layer 113. By the bias insulating layer 113, the bias electrode 170 and the active layer 130 may be separated from each other.

One end of the active layer 130 may be connected to the first electrode 161, and the other end of the active layer 130 may be connected to the second electrode 162.

Referring to FIG. 14G, a gate insulating layer 140 is formed on an active layer 130, and a gate electrode 150 is formed on the gate insulating layer 140. In detail, the gate electrode 150 is formed on an inclined surface 120s spaced apart from the active layer 130.

At least a portion of the gate electrode 150 and at least a portion of the active layer 130 are formed to overlap the bias electrode 170.

As a result, a thin film transistor 100 according to one embodiment of the present disclosure may be formed.

Hereinafter, a display apparatus including the thin film transistor described above is described.

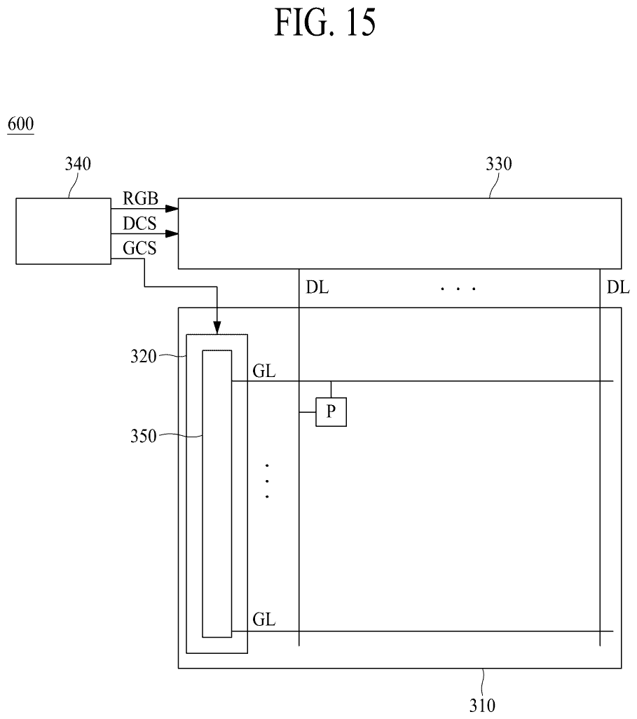

FIG. 15 is a schematic diagram of a display apparatus 600 according to another embodiment of the present disclosure.

A display apparatus 600 according to another embodiment of the present disclosure may include a display panel 310, a gate driver 320, a data driver 330, and a control unit 340.

The gate lines GL and the data lines DL are disposed on the display panel 310, and pixels P are disposed in the intersection area of the gate lines GL and data lines DL. An image is displayed by driving the pixels P.

The control unit 340 controls the gate driver 320 and the data driver 330.

The control unit 340 outputs a gate control signal GCS for controlling the gate driver 320 and a data control signal DCS for controlling the data driver 330 using a signal supplied from an external system. In addition, the control unit 340 samples input image data input from an external system, rearranges it, and supplies the rearranged image data RGB to the data driver 330.

The gate control signal GCS may include a gate start pulse GSP, a gate shift clock GSC, a gate output enable signal GOE, a start signal Vst, a gate clock GCLK, or the like. In addition, the gate control signal GCS may include control signals for controlling a shift register.

The data control signal DCS may include a source start pulse SSP, a source shift clock signal SSC, a source output enable signal SOE, a polarity control signal POL, or the like.

The data driver 330 supplies data voltage to the data lines DL of the display panel 310. In detail, the data driver 330 may convert image data RGB input from the control unit 340 into analog data voltage and supply the data voltage to the data lines DL.

The gate driver 320 sequentially supplies gate pulses GP to the gate lines GL during one frame. Here, one frame refers to a period during which one image is output through the display panel. In addition, the gate driver 320 supplies a gate off signal Goff capable of turning off the switching element to the gate lines GL during the remaining period during which the gate pulse GP is not supplied during one frame. Hereinafter, the gate pulse GP and the gate off signal Goff are collectively referred to as a scan signal SS.

According to one embodiment of the present disclosure, the gate driver 320 may be mounted on the substrate 110. As described above, a structure in which the gate driver 320 is directly mounted on the substrate 110 is called a Gate In Panel (GIP) structure.

The gate driver 320 includes a plurality of thin film transistors. The gate driver 320 may include the thin film transistors 100, 200, 300 or thin film transistor units 400, 500 described above.

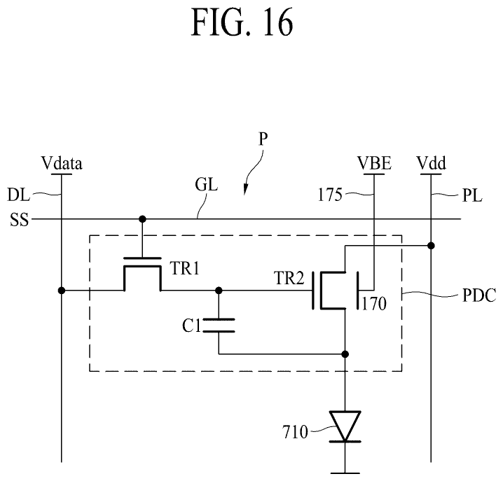

FIG. 16 is a circuit diagram for one pixel P of FIG. 15.

The circuit diagram of FIG. 16 is an equivalent circuit diagram for a pixel P of a display apparatus 600 including an organic light emitting diode (OLED) as a display element 710.

The pixel P includes a display element 710 and a pixel driver PDC that drives the display element 710. The pixel driver PDC includes a first thin film transistor TR1 and a second thin film transistor TR2.

In FIG. 16, a pixel P to which a thin film transistor 100, 200, 300 according to embodiments of the present disclosure is applied as a second thin film transistor TR2 is exemplarily illustrated. However, another embodiment of the present disclosure is not limited thereto, and a thin film transistor 100, 200, 300 according to embodiments of the present disclosure may be applied as a first thin film transistor TR1.

Additionally, the thin film transistor unit 400, 500 according to embodiments of the present disclosure may be applied to the first thin film transistor TR1 and the second thin film transistor TR2 of FIG. 16.

The first thin film transistor TR1 is connected to the gate line GL and the data line DL, and is turned on or off by the scan signal SS supplied through the gate line GL.

The data line DL provides a data voltage Vdata to the pixel driver PDC, and the first thin film transistor TR1 controls the application of the data voltage Vdata.

The driving power line PL provides a driving voltage Vdd to the display element 710, and the second thin film transistor TR2 controls the driving voltage Vdd. The driving voltage Vdd is a pixel driving voltage for driving the organic light emitting diode OLED, which is the display element 710.

When the first thin film transistor TR1 is turned on by a scan signal SS applied through the gate line GL from the gate driver 320, the data voltage Vdata supplied through the data line DL is supplied to the gate electrode of the second thin film transistor TR2 connected to the display element 710. The data voltage Vdata is charged in the first capacitor C1 formed between the gate electrode and the source electrode of the second thin film transistor TR2. The first capacitor C1 is a storage capacitor Cst.

The amount of current supplied to the organic light emitting diode (OLED), which is a display element 710, through the second thin film transistor TR2 is controlled according to the data voltage Vdata, and accordingly, the gradation of light output from the display element 710 may be controlled.

The second thin film transistor TR is provided with a bias electrode 170. A bias voltage VBE is supplied to the bias electrode 170 through a bias wire 175. The bias voltage VBE may have a negative (−) value.

The display element 710 illustrated in FIG. 16 is an organic light emitting diode (OLED). Accordingly, the display apparatus 600 according to one embodiment of the present disclosure is an organic light emitting display apparatus.

The pixel driver PDC according to another embodiment of the present disclosure may be formed in various structures other than the structures described above. The pixel driver PDC may include, for example, three or more thin film transistors and two or more capacitors.

The present disclosure described above is not limited to the above described embodiments and the attached drawings, and it will be apparent to a person skilled in the art to which the present disclosure pertains that various substitutions, modifications, and changes are possible within a scope that does not depart from the technical details of the present disclosure.

The thin film transistor according to one embodiment of the present disclosure has a vertical structure including a channel part disposed on an inclined surface of a buffer layer. Since the channel part has a vertical structure, the channel part may be formed in a small area. Accordingly, the area occupied by the thin film transistor according to one embodiment of the present disclosure is small. In addition, when the thin film transistor according to one embodiment of the present disclosure is used, integration of elements is possible.

The thin film transistor according to one embodiment of the present disclosure includes a bias electrode. By the bias electrode, a threshold voltage of the thin film transistor may be reduced or prevented from rolling off or shifting in a negative direction.

In one embodiment of the present disclosure, a high mobility oxide semiconductor layer is disposed on a side farther from the gate electrode in the active layer. Accordingly, the thin film transistor may have excellent current characteristic due to the high mobility oxide semiconductor layer, while the threshold of the thin film transistor may be reduced or prevented from shifting in the negative direction.

The display apparatus according to one embodiment of the present disclosure including such a thin film transistor may be manufactured with a high resolution and have stable and excellent display characteristic.

In addition to the effects mentioned above, other features and advantages of the present disclosure are described below or may be clearly understood by those skilled in the art to which the present disclosure pertains from such description and explanation.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin film transistor comprising:
a buffer layer having an inclined surface;
a bias electrode in the buffer layer;
an active layer spaced apart from the bias electrode, the active layer being disposed on the inclined surface of the buffer layer; and
a gate electrode spaced apart from the active layer, the gate electrode at least partially overlapping the active layer;
wherein the gate electrode overlaps the active layer on the inclined surface of the buffer layer, and
wherein the active layer includes a channel part, and the channel part overlaps the bias electrode.

2. The thin film transistor of claim 1,
wherein the buffer layer includes a first buffer layer and a second buffer layer on the first buffer layer, and
wherein the bias electrode is between the first buffer layer and the second buffer layer.

3. The thin film transistor of claim 1,
wherein the bias electrode extends across an entire width of the channel part along a width direction of the channel part,
wherein a width of the bias electrode is greater than a width of the channel part, and
wherein the width direction is a direction perpendicular to a direction in which current flows through the channel part.

4. The thin film transistor of claim 1,
wherein a thickness of the bias electrode is 30 nm to 50 nm.

5. The thin film transistor of claim 1 further comprising:
a bias insulating layer on the inclined surface of the buffer layer,
wherein the bias insulating layer is between the active layer and the bias electrode.

6. The thin film transistor of claim 5,
wherein a thickness of the bias insulating layer is equal to or greater than 3 nm.

7. The thin film transistor of claim 1 further comprising:
a first electrode and a second electrode spaced apart from each other and respectively connected to the active layer,
wherein at least one of the first electrode and the second electrode is on the buffer layer.

8. The thin film transistor of claim 7,
wherein the bias electrode does not overlap the first electrode and the second electrode.

9. The thin film transistor of claim 1,
wherein the active layer includes a first oxide semiconductor layer and a second oxide semiconductor layer on the first oxide semiconductor layer,
wherein the second oxide semiconductor layer is closer to the gate electrode than the first oxide semiconductor layer, and
wherein a thickness of the first oxide semiconductor layer is equal to or less than 50% of a total thickness of the active layer.

10. The thin film transistor of claim 9,
wherein the first oxide semiconductor layer has a higher mobility than the second oxide semiconductor layer.

11. The thin film transistor of claim 10,
wherein the first oxide semiconductor layer includes at least one of InO based oxide semiconductor material, IZO (InZnO) based oxide semiconductor material, ITZO based oxide semiconductor material, IGZO based oxide semiconductor material, FIGZO based oxide semiconductor material, and FIZO based oxide semiconductor material.

12. The thin film transistor of claim 11,
wherein a negative voltage is applied to the bias electrode.

13. The thin film transistor of claim 9,
wherein a thickness of the first oxide semiconductor layer is equal to or less than 5 nm.

14. The thin film transistor of claim 9,
wherein the active layer further comprises a third oxide semiconductor layer between the bias electrode and the first oxide semiconductor layer, and
wherein the first oxide semiconductor layer is between the second oxide semiconductor layer and the third oxide semiconductor layer.

15. A thin film transistor unit comprising:
a buffer layer, a first thin film transistor, and a second thin film transistor,
wherein the buffer layer includes a first inclined surface and a second inclined surface,
wherein the first thin film transistor comprises:
a first bias electrode at the first inclined surface in the buffer layer;
a first active layer spaced apart from the first bias electrode, the first active layer is disposed on the first inclined surface; and
a first gate electrode spaced apart from the first active layer, the first gate electrode at least partially overlaps the first active layer on the first inclined surface,
wherein the first active layer comprises a first channel part overlapping the first gate electrode, and
wherein the first channel part overlaps the first bias electrode; and
wherein the second thin film transistor comprises:
a second bias electrode at the second inclined surface in the buffer layer;
a second active layer spaced apart from the second bias electrode, the second active layer is disposed on the second inclined surface; and
a second gate electrode spaced apart from the second active layer, the second gate electrode at least partially overlaps the second active layer on the second inclined surface,
wherein the second active layer comprises a second channel part overlapping the second gate electrode, and
wherein the second channel part overlaps the second bias electrode.

16. The thin film transistor unit of claim 15, further comprising:
a first electrode on the buffer layer, the first electrode contacting the first active layer and the second active layer;
a second electrode spaced apart from the first electrode, the second electrode contacting the first active layer; and
a third electrode spaced apart from the first electrode, the third electrode contacting the second active layer.

17. The thin film transistor unit of claim 16,
wherein the second electrode and the third electrode are connected to each other,
wherein the first bias electrode and the second bias electrode are connected to each other, and
wherein a voltage applied to the first gate electrode is with the same as a voltage applied to the second gate electrode.

18. The thin film transistor unit of claim 16,
wherein a voltage applied to the second gate electrode is different from a voltage applied to the third electrode.

19. A display apparatus comprising:
a thin film transistor including:
a buffer layer having an inclined surface;
a bias electrode in the buffer layer;
an active layer spaced apart from the bias electrode, the active layer being disposed on the inclined surface of the buffer layer; and
a gate electrode spaced apart from the active layer, the gate electrode at least partially overlapping the active layer; and
a bias wire applying a voltage to the bias electrode,
wherein the gate electrode overlaps the active layer on the inclined surface of the buffer layer, and
wherein the active layer includes a channel part, and the channel part overlaps the bias electrode.

20. A manufacturing method of a thin film transistor comprising:
forming a first buffer layer on a substrate;
forming a bias electrode on the first buffer layer;
forming a second buffer layer on the bias electrode;
patterning the first buffer layer and the second buffer layer to form an inclined surface;
forming an active layer on the inclined surface; and
forming a gate electrode spaced apart from the active layer on the inclined surface,
wherein during formation of the inclined surface, at least a portion of the bias electrode is exposed from the inclined surface, and
at least a portion of the active layer and at least a portion of the gate electrode overlap the bias electrode.

21. The manufacturing method of claim 20, further comprising:
forming a bias insulating layer on the second buffer layer after forming the inclined surface and before forming the active layer,
wherein the bias insulating layer is formed on the inclined surface, and the bias insulating layer separates the active layer from the bias electrode.
